(19) United States
(12) Patent Application Publication
(10) Pub. No.: US 2011/0062489 A1
(43) Pub. Date: Mar. 17, 2011

(54) POWER DEVICE WITH SELF-ALIGNED SILICIDE CONTACT

(76) Inventors: Donald R. Disney, Cupertino, CA (US); Ognjen Milic, San Jose, CA (US)

(21) Appl. No.: 12/557,841

(22) Filed: Sep. 11, 2009

(51) Int. Cl. H01L 29/739; H01L 29/78; H01L 21/82

(52) U.S. Cl. 257/140; 257/329; 438/138; 257/341; 257/E21.602; 257/E29.198; 257/E29.257

(57) ABSTRACT

An improved power device with a self-aligned suicide and a method for fabricating the device are disclosed. An example power device is a vertical power device that includes contacts formed on gate and body contact regions by an at least substantially self-aligned silicidation (e.g., salicide) process. The example device may also include one or more sidewall spacers that are each at least substantially aligned between edges of the gate region and the body contact region. The body contact region may also be implanted into the device in at least substantial self-alignment to the sidewall spacer. The method may also include an at least substantially self-aligned silicon etch.

### TECHNICAL FIELD

The present disclosure is directed to semiconductor devices and processes, for example, to power devices and to the fabrication of power devices.

### BACKGROUND

Power devices (e.g., metal oxide semiconductor field effect transistors (MOSFETs), insulated gate bipolar transistors (IGBTs), superjunction MOSFETs, vertical double-diffused metal oxide semiconductor (VDMOS) devices, vertical metal oxide semiconductor (VMOS) devices, etc.) are often characterized by a number of device characteristics. For example, relatively high breakdown voltages, relatively large safe operating areas (SOAs), relatively low resistances, and/or the like are generally desirable. Likewise, relatively low fabrication cost and relatively high fabrication yield are also generally desirable.

A typical VDMOS device (not shown) may include a P-body region that is aligned to a polysilicon gate. An N+ source region and a P+ body contact region may also be formed in the P-body region. The SOA of typical VDMOS devices is inversely related to the length of the N+ source region; however, the length of typical N+ source regions may be limited by process tolerances for masking (e.g., photolithography) and alignment processes.

Typical VDMOS fabrication employs multiple photolithography steps to mask the wafer before and/or between other fabrication steps (e.g., deposition, diffusion, etching, etc). Fabrication costs may be reduced and fabrication yield increased by reducing the number of masking steps.

### BRIEF DESCRIPTION OF THE DRAWINGS

Non-limiting and non-exhaustive embodiments of the present invention are described with reference to the following drawings. In the drawings, like reference numerals refer to like parts throughout the various figures unless otherwise specified. These drawings are not necessarily drawn to scale. Likewise, the relative sizes of elements illustrated by the drawings may differ from the relative size depicted.

For a better understanding of the present invention, reference will be made to the following Detailed Description, which is to be read in association with the accompanying drawings, wherein:

FIG. 1 is a cross-sectional view of an embodiment of a vertical power device;

FIGS. 2A-2H illustrate a method of fabricating the vertical power device of FIG. 1 according to an embodiment of the invention; and

FIG. 3 illustrates a method of fabricating a vertical power device according to another embodiment of the invention.

### DETAILED DESCRIPTION

The following description provides specific details for a thorough understanding of, and enabling description for, various embodiments of the technology. One skilled in the art will understand that the technology may be practiced without many of these details. In some instances, well-known structures and functions have not been shown or described in detail to avoid unnecessarily obscuring the description of the embodiments of the technology. It is intended that the terminology used in the description presented below be interpreted in its broadest reasonable manner, even though it is being used in conjunction with a detailed description of certain embodiments of the technology. Although certain terms may be emphasized below, any terminology intended to be interpreted in any restricted manner will be overtly and specifically defined as such in this Detailed Description section. Likewise, terms used to describe a position or location, such as “under,” “below,” “over,” “above,” “right,” “left,” and similar, are used relative to the orientation of the illustrated embodiments and are intended to encompass similar structures when rotated into the illustrated orientation. The term “based on” or “based upon” is not exclusive and is equivalent to the term “based, at least in part, on” and includes being based on additional factors, some of which are not described herein. References in the singular are made merely for clarity of reading and include plural references unless plural references are specifically excluded. The term “or” is an inclusive “or” operator and is equivalent to the term “and/or” unless specifically indicated otherwise. In the description that follows, the scope of the term “some embodiments” is not to be so limited as to mean more than one embodiment, but rather, the scope may include one embodiment, more than one embodiment, or perhaps all embodiments.

An improved power device with a self-aligned silicide and a method for fabricating the device are disclosed. An example power device is a vertical power device that includes contacts formed on gate and body contact regions by an at least substantially self-aligned silicidation (e.g., salicide) process. The example device may also include one or more sidewall spacers that are each at least substantially aligned between edges of the gate region and the body contact region. The body contact region may also be implanted into the device in at least substantial self-alignment to the sidewall spacer. The method may also include an at least substantially self-aligned silicon etch.

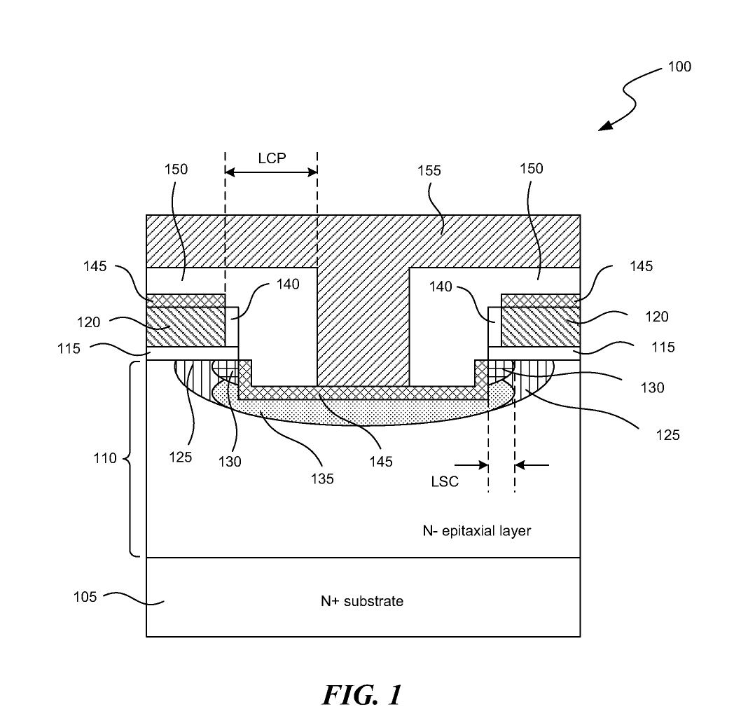

FIG. 1 illustrates a cross-sectional view of vertical power device 100. Vertical power device 100 may be a vertical double-diffused metal oxide semiconductor (VDMOS) device having a planer gate structure. Vertical power device 100 may also be configured as a relatively high breakdown voltage and relatively low resistance power device with a relatively large safe operating area (SOA).

As illustrated, vertical power device 100 includes N− epitaxial layer 110 formed on N+ substrate 105. Gate oxide layer 115 also spaces polysilicon gate region 120 apart from N− epitaxial layer 110. P-body region 125, N+ source region 130, and P+ body contact region 135 are formed within N− epitaxial layer 110, with P-body region 125 at least substantially (e.g., to within process tolerances) including N+ source region 130 and P+ body contact region 135.

In addition, sidewall spacer 140 is illustrated in at least substantial alignment between an edge of polysilicon gate region 120 and an edge of P+ body contact region 135 and may enable silicide layer 145 to be formed in at least substantial self-alignment with polysilicon gate region 120 and P+ body contact region 135. As shown, vertical power device 100 also includes interlevel dielectric (ILD) 150 that is in contact with silicide layer 145. Metal electrode 155, which is coupled to the portion of silicide layer 145 above P+ body contact region 135, is also in contact with ILD 150.

Although illustrated in cross-sectional view, elements of vertical power device 100 may be formed in an annular configuration. For example, gate oxide layer 115, polysilicon gate region 120, P-body region 125, N+ source region 130, the portion of silicide layer 145 over polysilicon gate region 120, and ILD 150 may be formed in an annular configuration (e.g., relative to metal electrode 155, ILD 150, the portion of silicide layer 145 over P+ body contact region 135, etc.).

As one example, use of sidewall spacer 140 and the techniques described herein enables fabrication of vertical power device 100 with a less than typical number of masking processes and with reduced reliance on masking process tolerances. For example, vertical power device 100 may be fabricated with N+ source region 130 having a relatively short length of between 0.1 to 0.3 microns, which is smaller than is typically fabricated through traditional masking-based fabrication.

As compared to conventionally fabricated devices, vertical power device 100 may also have a longer contact-to-polysilicon length (LCP) and a shorter N+ source length (LSC). A longer LCP may, in effect, reduce reliance on process tolerances of masking-based alignment processes for metal electrode 155 and polysilicon gate 120. A shorter LSC may reduce the likelihood of vertical power device 100's being affected with a parasitic bipolar effect that could lead to damage of the device. In the illustrated example, the relatively short LSC may enable an approximately three to five times increase in SOA, as compared to a conventionally fabricated device. In addition, fabrication costs for vertical power device 100 may be lower than that for a conventional power device due to the increased number of self-aligned processes instead of masking processes.

Although illustrated with respect to a VDMOS device, the technology described herein is also applicable to other power devices, such as those described above, other planer gate devices, lateral power devices, N-channel devices, P-channel devices, and/or the like.

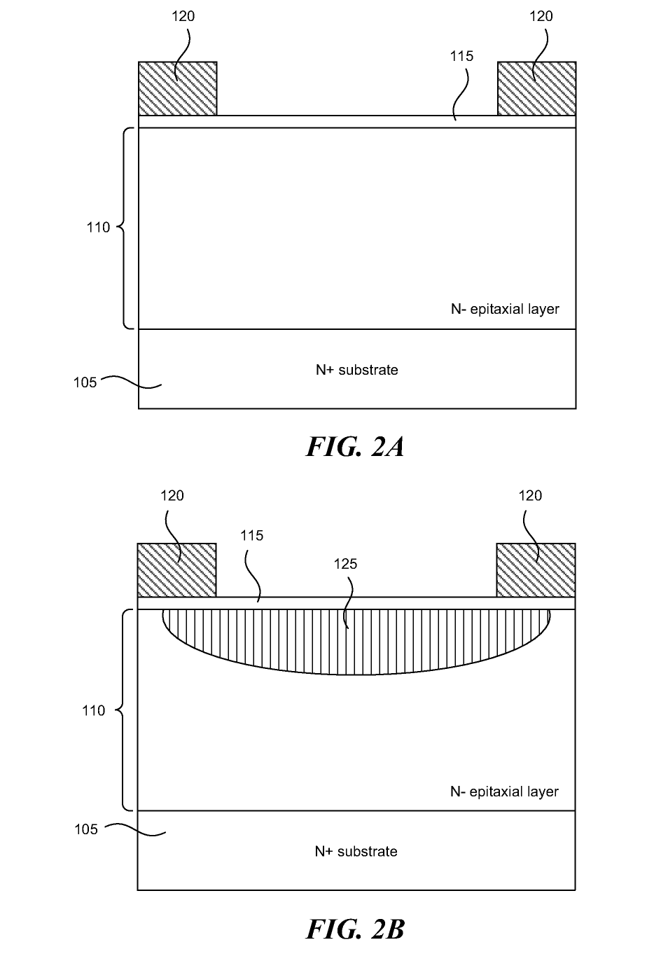

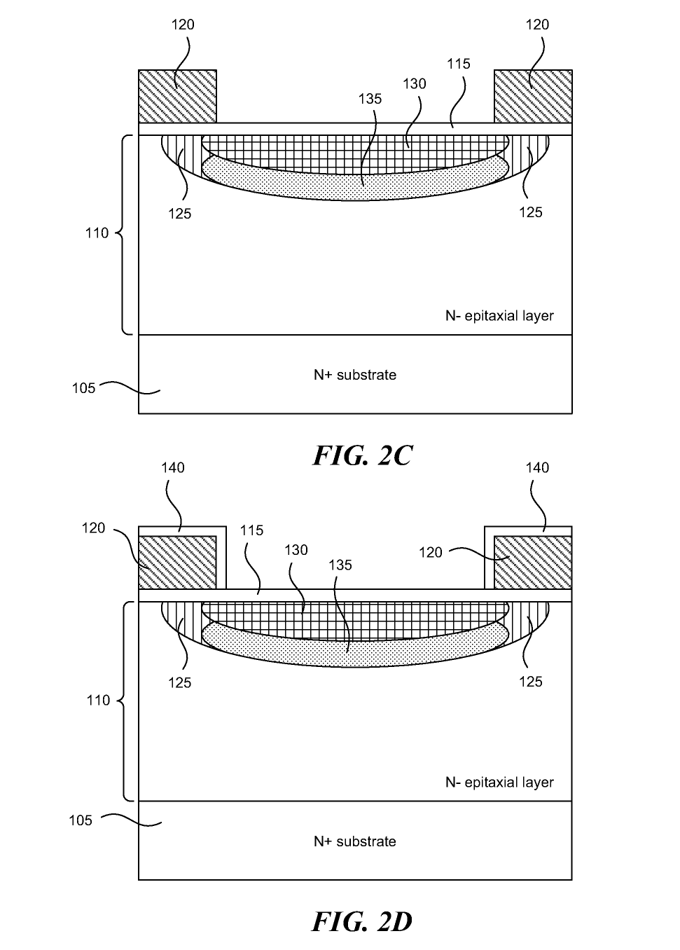

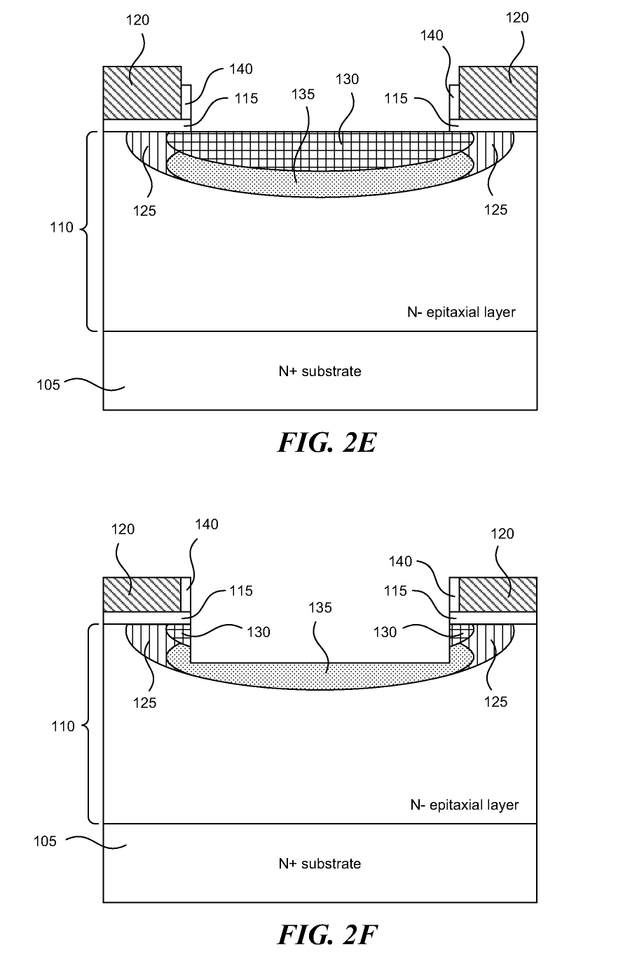

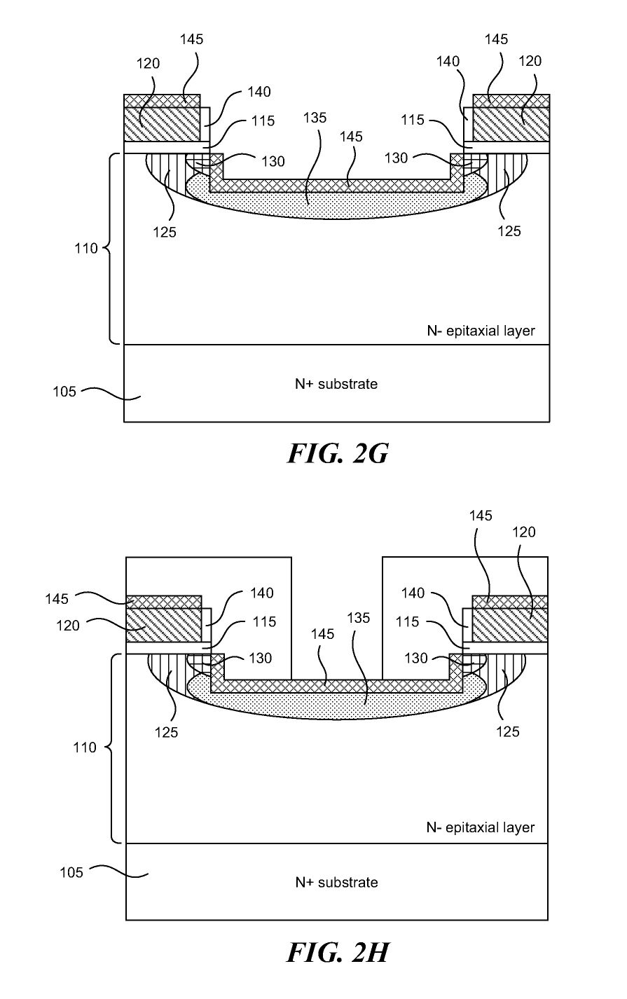

Additional aspects of vertical power device 100 are described below with reference to FIGS. 2A-2H.

FIGS. 2A-2H illustrate a method of fabricating vertical power device 100 of FIG. 1.

FIG. 2A illustrates a structure of vertical power device 100 after respective formation of N− epitaxial layer 110 onto N+ substrate 105, gate oxide layer 115 onto N− epitaxial layer 110, and polysilicon gate region 120 onto gate oxide layer 115. Forming polysilicon gate region 120 may include forming a doped polysilicon layer, masking the doped polysilicon layer, and etching the unmasked areas. Gate oxide layer 115 may be formed using oxide growth techniques and have a thickness that optimizes various attributes, such as those discussed above, of power transistor 100. For example, a thickness of 400 to 1000 angstroms may be suitable for a high-voltage VDMOS transistor. However, other processes may be employed to form an oxide as gate oxide 115, other suitable dielectrics may be employed instead of a gate oxide, and/or the like.

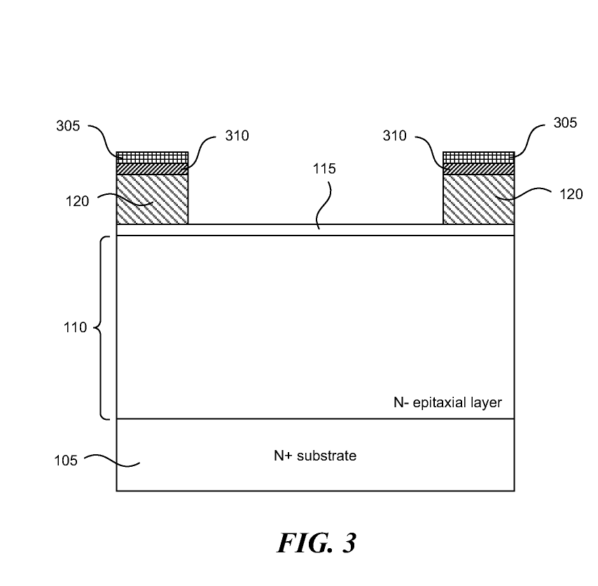

In at least one embodiment, N− epitaxial layer 110 may have a thickness and/or doping concentration based on a breakdown voltage requirement or other suitable criteria. For example, a doping of 1×10¹⁴ cm⁻³ and thickness of 50 microns may be suitable for a VDMOS with breakdown voltage of 700V. Likewise, polysilicon gate region 120 may be a relatively thick polysilicon region (e.g., in the order of 6,000 to 10,000 angstroms) that is sufficient to block/self-mask later implants, diffusions, and/or the like (e.g., implantation of P+ body contact region 135). As one example, polysilicon gate region 120 may be approximately 7,000 angstroms thick. However, any suitable thickness or additional layers may be employed (e.g., as described below with reference to FIG. 3). In one embodiment, the initial thickness of polysilicon gate 120 is determined as a sum of a specified final thickness of polysilicon gate 120 and the thickness of the polysilicon that will be etched during the silicon etch process described below.

In addition to the processes described above, field oxide areas (not shown) may be optionally defined (e.g., by a masking process) for the edge termination regions. An optional unmasked N-type implant (not shown) may also be implanted into N− epitaxial layer 110 to reduce the resistance of the junction field effect transistor (JFET) formed between adjacent P-body region 125.

FIG. 2B corresponds to implantation of P-body region 125 into N− epitaxial layer 110. The implant conditions may be chosen to optimize the device performance. For example a boron implant with dose of 2×10¹³ cm⁻² to 8×10¹³ cm⁻² and energy of 20 keV to 80 keV may be employed and driven into N− epitaxial layer 110 (e.g., to laterally diffuse P-body region 125 under polysilicon gate region 120, to form a channel region of vertical power device 100). By way of example, a diffusion temperature of approximately 1100° C. and diffusion time of 60 to 120 minutes may be employed to achieve a channel length of 1.5 to 3.0 microns. As shown, P-body region 125 is at least substantially self-aligned to the edge of polysilicon gate region 120. Use of the techniques described above avoids the need for a dedicated mask step for the formation of P-body region 125. However, P-body region 125 may be aligned to other elements or formed with any other suitable technique.

As shown in FIG. 2C, N+ source region 130 and P+ body contact region 135 are then implanted into N− epitaxial layer 110. As illustrated, both N+ source region 130 and P+ body contact region 135 are at least substantially self-aligned to polysilicon gate region 120. In one embodiment, N+ source region 130 is formed by arsenic implanted at an energy of 100 keV to 150 keV and dose of 2×10¹⁵ cm⁻² to 5×10¹⁵ cm⁻², although other suitable dopants, doses, and energies may be used. The thickness of gate oxide 115 may be reduced prior to this implantation, to allow more of the implanted dopant to enter the silicon. N+ source region 130 and P+ body contact region 135 may be diffused at the same time, or alternately N+ source region 130 may be driven-in before P+ body contact region 135 is implanted (e.g., to avoid diffusing P+ body contact region 135 while diffusing N+ source region 130).

P+ body contact region 135 may be implanted with a relatively high energy (e.g., boron with a dose in the range of 1×10¹⁴ cm⁻² to 1×10¹⁶ cm⁻², and with an energy in the range of 100 keV to 200 keV), or at any other suitable dose and energy. As one example, P+ body contact region 135 is implanted with a dose of approximately 1×10¹⁵ cm⁻², and with an energy of approximately 150 keV. A relatively high energy and dose may result in a relatively low resistance in the portion of P-body region 125 under N+ source region 130, which generally improves SOA, as described above, and may reduce the possibility that the implant laterally scatters into the channel, which could adversely affect the threshold voltage or other parameters of power device 100.

In other embodiments, P+ body contact region 135 is implanted later in the fabrication process (e.g., after formation of sidewall spacer 145 or after a silicon etch process). These embodiments are described in more detail below.

Although FIGS. 2B and 2C illustrate separate processes for forming P-body region 125 and P+ body contact region 135, in other embodiments a retrograde P-well may be employed instead of P-body region 125 and P+ body contact region 135.

Referring now to FIG. 2D, a dielectric layer, a portion of which later forms sidewall spacer 140, is deposited over polysilicon gate region 120. As one example, sidewall spacer 140 may be formed of silicon dioxide, silicon nitride, and/or any other suitable dielectric materials. In addition, the dielectric layer may be formed as a conformal layer. In one embodiment, the thickness of the conformal layer will later define the width of sidewall spacer 140 and N+ source region 130 and may be between 2,000 and 7,000 angstroms thick. However, any suitable thickness may be employed.

Corresponding to FIG. 2E, the dielectric layer is then etched to form sidewall spacer 140 along polysilicon gate region 120 in at least substantial alignment with an edge of polysilicon gate region 120. As one example, an anisotropic dielectric etching process having a faster dielectric etch rate than silicon etch rate may be employed such that polysilicon gate region 120 and N− epitaxial layer 110 are substantially unchanged as sidewall spacer 140 is formed. The length of the etching process may also be selected to form sidewall spacer 140 to any suitable height. As illustrated, sidewall spacer 140 is formed to be lower than the top of polysilicon gate region 120. In this example, the processes corresponding to FIG. 2F will further reduce the thickness of polysilicon gate region 120 to be substantially level with the top of sidewall spacer 140. However, sidewall spacer 140 may be etched to any suitable height.

As an alternative to the processes corresponding to FIG. 2C, P+ body contact region 135 may be implanted after the deposition of the dielectric layer of FIG. 2D and either before or after the etching process of FIG. 2E. In such an example, P+ body contact region 135 would then be at least substantially self-aligned to sidewall spacer 140, instead of to polysilicon gate region 120. This alternative would result in more lateral separation between P+ body contact region 135 and the channel, reducing the possibility of adverse effects on the threshold voltage or other parameters of power device 100.

Referring now to FIG. 2F, polysilicon gate region 120 and N− epitaxial layer 110 are then etched using a process that, for example, etches silicon at a substantially higher rate than it etches oxide (or other materials used for sidewall spacers 145). As illustrated, this silicon etch penetrates into N− epitaxial layer 110, exposing N+ source region 130 and P+ body contact region 135. As shown, this trench etch is at least substantially self-aligned to sidewall spacer 140. Due to the self-aligned nature of this trench etch, the N+ source length LSC of FIG. 1 is independent of masking-process tolerances and may be more accurately controlled. This may result in a relatively short LSC and relatively low likelihood of parasitic bipolar effects.

As shown, polysilicon gate region 120 may be etched by approximately the same amount as N− epitaxial layer 110, depending on the relative etch rates of polysilicon gate 120 and N− epitaxial layer 110. For this example, the earlier formed polysilicon layer (e.g., corresponding to FIG. 2A) may be formed at a thickness that accounts for this etching. However, as described in further detail with respect to FIG. 3, protective layers may be formed on polysilicon gate region 120 to prevent etching of polysilicon gate region 120 during the silicon etch process.

As an alternative to the processes corresponding to FIG. 2C, P+ body contact region 135 may be implanted after the silicon etch process corresponding to FIG. 2F and before the silicide process corresponding to FIG. 2G. In such an example, P+ body contact region 135 would be at least substantially self-aligned to sidewall spacer 140, instead of to polysilicon gate region 120. This alternative could result in more lateral separation between P+ body contact region 135 and the channel, reducing the possibility of adverse effects on the threshold voltage or other parameters of power device 100. Performing the implantation of P+ body contact region 135 implant after the silicon etch process may also have the further advantage of lowering the required implant energy, for example, because the overlying N+ source region has been removed such that there is an exposed portion of P-body region 125 to receive the P+ implant. In this example, an implant energy of 20 keV to 80 keV may be used to achieve a similar result to the use of an implant energy of 100 keV to 200 keV, to implant P+ body contact region 135 through overlying N+ source region 125 of FIG. 2C. Following implantation of P+ body contact region 135 in this embodiment, a rapid-thermal anneal (RTA) or suitable furnace anneal process may be employed to activate the P+ implant and possibly to diffuse it laterally under N+ source region 125.

FIG. 2G corresponds to the formation of silicide layer 145 in at least substantial self-alignment with sidewall spacer 140. As silicide generally does not form on sidewall spacer 140, sidewall spacer 140 provides separation between the portion of silicide layer 145 over polysilicon gate region 120 and the portion of silicide layer 145 over P+ body contact region 135.

Silicide layer 145 may also provide a relatively low resistance connection between N+ source region 130, P+ body contact region 135, and the yet-to-be-formed metal electrode 155. In certain embodiments, this relatively low-resistance connection increases the SOA and improves switching performance. In one embodiment, silicide layer 145 may include multiple layers. For example, silicide layer 145 may include 200 to 600 angstroms of titanium silicide plus 100 to 200 angstroms of titanium nitride. In this example, silicide layer 145 has a sheet resistance of approximately 3 ohms/square to 5 ohms/square, which provides more gate resistance than the typical doped polysilicon gate material resistance of approximately 10 ohms/square to 20 ohms/square. However, a silicide having any other appropriate resistance may be employed.

Now turning to FIG. 2H, interlevel dielectric (ILD) 150 is deposited, masked, and etched to form a contact opening for metal electrode 155. The material of ILD 150 may be a single layer or a combination of dielectric materials used in other ILD processes. For example, undoped or doped silicon dioxide may be deposited at a thickness of 1 to 2 microns. The alignment of the contact openings and the edges of polysilicon gate 120 may be much less critical for this process as compared to fabrication processes, because a low-resistance contact to N+ source region 125 and P+ body contact region 135 is provided by silicide layer 145. A metallization process may then be performed to form metal electrode 155 and to result in vertical power device 100 of FIG. 1. As one example, the metallization may formed through deposition of an aluminum alloy with a thickness in the range of 2 to 5 microns, followed by masking and etching processes. However, any other suitable process steps may be employed. In addition, deposition, masking, and etching processes may also be optionally performed to form a passivation layer (not shown).

FIG. 3 illustrates a method of fabricating another vertical power device. In comparison to FIG. 2A, FIG. 3 further includes polysilicon protect layer 305 and oxide protect layer 310. With such a device, polysilicon gate region 120 may be formed at or near its final thickness and remain substantially unchanged during other processes.

Polysilicon protect layer 305 and oxide protect layer 310 may be formed from any suitable thickness of nitride, silicon dioxide, silicon nitride, and/or other appropriate materials. In fabricating such a device, polysilicon protect layer 305 protects oxide protect layer 310 and polysilicon gate region 120 from etching during the etching process described with reference to FIG. 2E and may be removed as part of the silicon etching process described with reference to FIG. 2F.

Oxide protect layer 310 may also protect polysilicon gate region 120 during the silicon etching process described with reference to FIG. 2F. For example, oxide protect layer 310 may be formed of a material that etches relatively slowly during the silicon etching process described with reference to FIG. 2F and thus protect polysilicon gate region 120 from significant etching. Oxide protect layer 310 may then be removed prior to the salicidation process described with reference to FIG. 2G. For example, oxide protect layer 310 may be removed through a selective wet etch such as a hydrofluoric acid etch or any other suitable process. As one example, nitride may be employed to form sidewall spacer 140, or an anisotropic etch may be performed such that sidewall spacer 140 remains substantially unchanged as oxide protect layer 310 is removed.

As yet another example, oxide protect layer 310 may be left on polysilicon gate region 120 (e.g., such that silicide is not formed on polysilicon gate region 120).

While the above Detailed Description describes certain embodiments of the invention, and describes the best mode contemplated, no matter how detailed the above appears in text, the invention can be practiced in many ways. Details of the system may vary in implementation, while still being encompassed by the invention disclosed herein. As noted above, particular terminology used when describing certain features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific embodiments disclosed in the specification, unless the above Detailed Description explicitly defines such terms. Accordingly, the actual scope of the invention encompasses not only the disclosed embodiments, but also all equivalent ways of practicing or implementing the invention under the claims.

We claim:

1. A power device, comprising:
a first layer;
a body contact region formed in the first layer;
a gate region spaced apart from the first layer by a gate oxide layer;
a sidewall spacer that is at least substantially aligned between an edge of the gate region and an edge of the body contact region;
a gate silicide region formed on the gate region; and
a body contact silicide region formed on the body contact region.

2. The device of claim 1, further comprising:
a metal electrode coupled to the body contact silicide region;
a semiconductor substrate, wherein the first layer is an epitaxial layer formed on the semiconductor substrate;
an interlevel dielectric in contact with the gate silicide region, the body contact silicide region, and in contact with the metal electrode;
a source region formed in the first layer; and
a body region formed in the first layer and that at least substantially includes the body contact region and the source region.

3. The device of claim 2, wherein the first layer is an N− epitaxial layer, the gate region is formed of polysilicon, the body contact region is a P+ implant region, the body region is a P-body implant region, and the source region is an N+ source implant region.

4. The device of claim 1, wherein each of the gate region and the gate silicide region is an annular region.

5. The device of claim 1, wherein the sidewall spacer is formed from a conformal layer of silicon dioxide or silicon nitride.

6. The device of claim 1, wherein the device is at least one of an N-channel or P-channel device having a planer gate structure.

7. The device of claim 1, wherein the device is at least one of a metal oxide semiconductor field effect transistor (MOSFET), an insulated gate bipolar transistor (IGBT), a superjunction MOSFET, a vertical double-diffused metal oxide semiconductor (VDMOS) device, or a vertical metal oxide semiconductor (VMOS) device.

8. The device of claim 1, wherein the gate silicide region is at least substantially self-aligned to the sidewall spacer, and wherein the body contact region is self-aligned to the sidewall spacer and was implanted with a dose in the range of 1×10¹⁴ cm⁻² to 1×10¹⁶ cm⁻², and with an energy in the range of 100 keV to 200 keV.

9. A power device, comprising:
a semiconductor substrate;
an epitaxial layer on the semiconductor substrate, the epitaxial layer having a first surface and including at least a body contact region, a source region, and a body region formed therein, wherein the body region at least substantially includes the body contact region and the source region;
a gate region above the first surface and spaced apart from the epitaxial layer by a gate dielectric layer;
a sidewall spacer that is at least substantially aligned between an edge of the gate region and an edge of the body contact region;
a gate silicide region formed on the gate region;
a body contact silicide region formed on the body contact region; and
an electrode coupled to the body contact silicide region.

10. The device of claim 9, wherein each of the gate region and the gate silicide region is in an annular configuration about the body contact region.

11. The device of claim 9, wherein the device is a vertical double-diffused metal oxide semiconductor (VDMOS) device having a planer gate structure.

12. The device of claim 9, wherein the sidewall spacer is formed from a conformal layer of silicon dioxide or silicon nitride, wherein the gate silicide region and the body contact silicide region are at least substantially self-aligned to the sidewall spacer.

13. The device of claim 9, wherein the body contact region is at least substantially self-aligned to the edge of the gate region and/or the sidewall spacer.

14. The device of claim 9, wherein the epitaxial layer defines a trench region that extends vertically into the epitaxial layer from the first surface to a trench depth that is greater than a depth of the source region, and wherein a lateral extent of the trench region is at least substantially aligned to the sidewall spacer.

15. The device of claim 14, wherein the body contact silicide region is at an end of trench region that is opposite the first surface.

16. The device of claim 14, wherein a sidewall of the trench region is adjacent a portion of the source region and the body contact silicide is configured to form an electrical contact with the exposed portion of the source region.

17. The device of claim 16, wherein the source region is at least substantially self-aligned between the edge of the gate region and the sidewall of the trench region.

18. The device of claim 14, wherein the body contact region is at least substantially self-aligned to the recess.

19. A method of fabricating a power device, comprising:
forming an epitaxial layer on a substrate;
forming a gate oxide on the epitaxial layer;
forming a polysilicon gate region on the gate oxide;
forming a sidewall spacer that is at least substantially aligned to an edge of the polysilicon gate region; and
(a) forming silicide layers on the polysilicon gate region and on the epitaxial layer, the silicide layers at least substantially self-aligned to the sidewall spacer;
(b) implanting a body contact region into the epitaxial layer;
(c) performing an etch, at least substantially self-aligned to the sidewall spacer, into the epitaxial layer; or
(d) a combination of (a), (b), and/or (c).

20. The method of claim 19, wherein forming the sidewall spacer includes:
depositing a conformal layer of silicon dioxide or silicon nitride; and
etching the deposited conformal layer to form a sidewall spacer in at least substantial alignment with an edge of the polysilicon gate.

21. The method of claim 19, wherein the method at least includes forming the silicide layers, and wherein the method further comprises:
depositing an interlevel dielectric onto the silicide layers and onto the sidewall spacer;
etching the deposited interlevel dielectric and exposing at least a portion of the silicide layers formed on the epitaxial layer; and
forming a metal electrode in contact with the exposed portion of the silicide layers.

22. The method of claim 19, wherein the method at least includes implanting the body contact region, and wherein the method further comprises:
implanting a body region, at least substantially self-aligned to the polysilicon gate region, into the epitaxial layer; and
implanting a source region, at least substantially self-aligned to the polysilicon gate region, into the epitaxial layer, wherein the body region at least substantially includes the body contact region and the source region.

23. The method of claim 22, wherein the body contact region is implanted at an energy such that the body contact region is substantially formed vertically beneath the source region.

24. The method of claim 19, wherein the method at least includes performing the etch into the epitaxial layer, and wherein the method further comprises:
implanting a body contact region after the etch into the epitaxial layer.

25. The method of claim 19, wherein the method at least includes implanting the body contact region, and wherein the method further comprises:
implanting the body contact region prior to the forming the sidewall spacer such that the body contact region is at least substantially self-aligned to the polysilicon gate region

26. The method of claim 19, wherein the method at least includes implanting the body contact region, and wherein the method further comprises:
implanting the body contact region after the forming the sidewall spacer such that the body contact region is at least substantially self-aligned to the sidewall spacer.

27. The method of claim 19, wherein the method at least includes forming the silicide layers and performing the etch into the epitaxial layer, and wherein the method further comprises:
forming the silicide layers after performing the etch into the epitaxial layer; and
forming a source region, wherein the suicide layer on the epitaxial layer is formed at a bottom of an etched trench and is in contact with sidewalls of the etched trench.

28. The method of claim 19, wherein the method at least includes performing the etch into the epitaxial layer, and wherein the method further comprises:
forming an oxide protect layer on the polysilicon gate region, the oxide protect layer at least partially protecting the polysilicon gate region during the etch into the epitaxial layer.

29. The method of claim 28, further comprising:
forming a polysilicon protect layer on the oxide protect layer, the polysilicon protect region at least partially protecting the polysilicon gate region during an etching to form the sidewall spacer; and
removing the polysilicon protect layer at substantially the same time as performing the etch into the epitaxial layer.
